(19) United States
(12) Patent Application Publication
(10) Pub. No.: US 2025/0293552 A1
(43) Pub. Date: Sep. 18, 2025

(54) WIRELESS POWER TRANSMISSION DEVICE FOR DETECTING FOREIGN OBJECT AND METHOD THEREOF

(71) Applicant: Samsung Electronics Co., Ltd., Suwon-si (KR)

(72) Inventors: Joonhong KIM, Suwon-si (KR); Jaehyun PARK, Suwon-si (KR); Seho PARK, Suwon-si (KR); Jaeseok PARK, Suwon-si (KR); Sungku YEO, Suwon-si (KR)

(21) Appl. No.: 19/221,173

(22) Filed: May 28, 2025

Related U.S. Application Data
(63) Continuation of application No. PCT/KR2023/016648, filed on Oct. 25, 2023.

(30) Foreign Application Priority Data
Dec. 23, 2022 (KR) 10-2022-0182969

(51) Int. Cl. H02J 50/60; H02J 50/12; H02J 50/40

(52) U.S. Cl. CPC H02J 50/60; H02J 50/12; H02J 50/402

(57) ABSTRACT

An electronic device may comprise: a resonator; a power circuit configured to provide power to the resonator; an antenna; a high-frequency source configured to provide power to the antenna; and a controller comprising circuitry. The controller may be configured to control the power circuit to: provide first power having a first frequency to the resonator to wirelessly provide power to an external wireless power reception device; control the high-frequency source to provide at least one second power having a different frequency from the first frequency to the antenna; identify at least one phase of impedance corresponding to the antenna while the at least one second power is applied to the antenna; identify the type of a foreign object adjacent to the electronic device based on the at least one phase. The antenna may be an antenna in which the same direction of current is formed by the at least one second power.

### CROSS-REFERENCE TO RELATED APPLICATIONS

This application is a continuation of International Application No. PCT/KR2023/016648 designating the United States, filed on Oct. 25, 2023, in the Korean Intellectual Property Receiving Office and claiming priority to Korean Patent Application No. 10-2022-0182969, filed on Dec. 23, 2022, in the Korean Intellectual Property Office, the disclosures of each of which are incorporated by reference herein in their entireties.

### BACKGROUND

### Field

The disclosure relates to a wireless power transmission device for detecting an external object and a method thereof.

### Description of Related Art

A wireless power transfer technology refers to a method of transmitting power using an electromagnetic field induced in a coil, which may supply electric energy by applying a current to a transmitting coil to generate an electromagnetic field and forming an induced current in a receiving coil by the generated electromagnetic field.

A wireless power transmission device may receive direct-current (DC) power, convert the DC power into alternating-current (AC) power, and generate an electromagnetic field through a resonator, thereby transmitting power to a wireless power reception device.

In a case where a foreign substance exists on the wireless power transmission device, the wireless power transmission efficiency of the wireless power transmission device may decrease or the wireless power transmission device may be damaged due to the foreign substance.

Therefore, a technology is required to detect an object existing on a wireless power transmission device and determine whether the object is a power transmission target.

### SUMMARY

According to an example embodiment, an electronic device may include: a resonator, a power circuit configured to provide power to the resonator, an antenna, a high-frequency source configured to provide power to the antenna, and a controller comprising circuitry. The controller may be configured to control the power circuit to: provide first power having a first frequency to the resonator to wirelessly provide power to an external wireless power reception device; control the high-frequency source to provide at least one second power having a frequency different from the first frequency to the antenna; identify at least one phase of impedance corresponding to the antenna while the at least second power is applied to the antenna; and identify a type of an external object adjacent to the electronic device, based on the at least one phase; wherein the antenna may include an antenna configured such that currents in the same direction are formed by the at least one second power.

According to an example embodiment, a method of operating an electronic device may include: controlling a power circuit of the electronic device to provide first power having a first frequency to a resonator of the electronic device to wirelessly provide power to an external wireless power reception device; controlling a high-frequency source of the electronic device to provide at least one second power having a frequency different from the first frequency to an antenna of the electronic device; identifying at least one phase of impedance corresponding to the antenna while the at least second power is applied to the antenna; and identifying a type of an external object adjacent to the electronic device, based on the at least one phase; wherein the antenna may include an antenna configured such that currents in the same direction are formed by the at least one second power.

According to an embodiment, a non-transitory computer-readable recording medium may store instructions which, when executed by a controller of an electronic device, cause the electronic device to perform at least one operation, the at least one operation may include: controlling a power circuit of the electronic device to provide first power having a first frequency to a resonator of the electronic device to wirelessly provide power to an external wireless power reception device; controlling a high-frequency source of the electronic device to provide at least one second power having a frequency different from the first frequency to an antenna of the electronic device; identifying at least one phase of impedance corresponding to the antenna while the at least second power is applied to the antenna; and identifying a type of an external object adjacent to the electronic device, based on the at least one phase; wherein the antenna may be configured such that currents in the same direction are formed by the at least one second power.

According to an example embodiment, an antenna included in an electronic device may include: an antenna configured such that currents in the same direction are formed by AC power applied to the antenna; and a controller, comprising circuitry, of the electronic device may be configured to cause the electronic device to: control a power circuit of the electronic device to provide first power having a first frequency to a resonator of the electronic device to wirelessly provide power to an external wireless power reception device; control a high-frequency source of the electronic device to provide at least one second power having a frequency different from the first frequency to the antenna; identify at least one phase of impedance corresponding to the antenna while the at least second power is applied to the antenna; and identify a type of an external object adjacent to the electronic device, based on the at least one phase.

### BRIEF DESCRIPTION OF THE DRAWINGS

The above and other aspects, features and advantages of certain embodiment of the present disclosure will be more apparent from the following detailed description, taken in conjunction with the accompanying drawings, in which:

FIG. 1 is a diagram illustrating an example operation of an electronic device included in a wireless charging system according to an embodiment;

FIG. 2 is a block diagram illustrating an example configuration of an electronic device according to an embodiment;

FIG. 3 is a diagram illustrating an example structure of an antenna according to an embodiment;

FIG. 4 is a graph illustrating the operating frequency of an antenna according to an embodiment;

FIG. 5 is a diagram illustrating an electric field around an antenna according to an embodiment;

FIG. 6 is a diagram illustrating an example structure of an antenna according to an embodiment;

FIGS. 7A and 7B are graphs illustrating an example operation of an electronic device according to an embodiment;

FIG. 8 is a flowchart illustrating an example operation of an electronic device according to an embodiment;

FIG. 9 is a diagram illustrating an example resonator and an example antenna according to an embodiment;

FIG. 10A is a diagram illustrating an example resonator and an example antenna according to an embodiment;

FIG. 10B is a diagram illustrating an example resonator and an example antenna according to an embodiment;

FIG. 11 is a graph illustrating the operating frequency of an antenna according to an embodiment;

FIG. 12 is a diagram illustrating the flow of a current in an antenna according to an embodiment;

FIG. 13 is a diagram illustrating an electric field around an antenna according to an embodiment;

FIG. 14 is a diagram illustrating an example structure of an antenna according to an embodiment;

FIG. 15 is a graph illustrating the operating frequency of an antenna according to an embodiment;

FIG. 16 is a graph illustrating an example operation of an electronic device according to an embodiment;

FIG. 17 is a graph illustrating an example operation of an electronic device according to an embodiment; and

FIG. 18 is a graph illustrating an example operation of an electronic device according to an embodiment.

### DETAILED DESCRIPTION

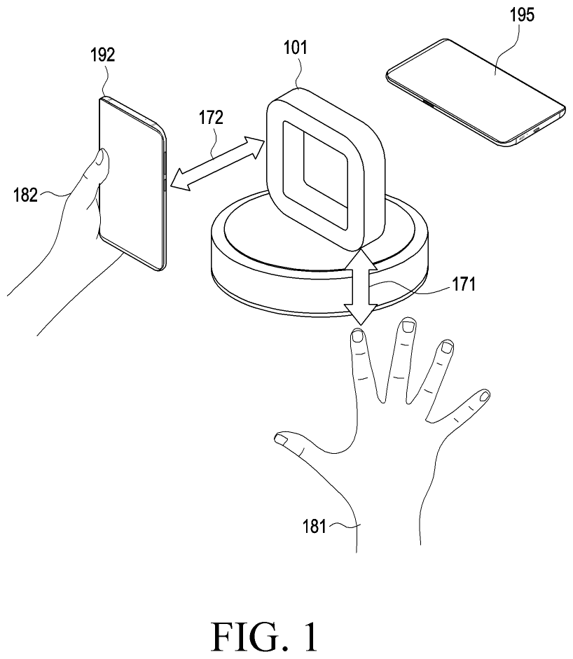

FIG. 1 is a diagram illustrating an example operation of an electronic device included in a wireless charging system according to an embodiment.

Referring to FIG. 1, the electronic device 101 according to an embodiment may identify the type of an external object (e.g., 181, 192, or 195 of FIG. 1) adjacent to the electronic device 101. For example, a first external object 181 may be positioned in a first direction 171 with respect to the electronic device 101. The electronic device 101 may identify the type of the first external object 181 adjacent to the electronic device 101 as a first type (e.g., a human body) according to an embodiment to be described in greater detail below. For example, a second external object 192 may be positioned in a second direction 172 with respect to the electronic device 101. The second direction 172 may be different from the first direction 171. In FIG. 1, a state in which the second external object 192 is gripped by a third external object 182 (e.g., a user's hand) is for illustration, and the second external object 192 may be positioned alone in the second direction 172. The electronic device 101 may identify the type of the second external object 192 adjacent to the electronic device 101 as a second type (e.g., a conductor) according to an embodiment to be described below. A method for the electronic device 101 to identify the type of an external object (e.g., 181 or 192 of FIG. 1) will be described below. Referring to FIG. 1, the electronic device 101 may identify the type of the external object (e.g., 181 or 192 of FIG. 1) adjacent to the electronic device 101 regardless of a direction in which the external object (e.g., 181 or 192 of FIG. 1) is positioned.

Referring to FIG. 1, the electronic device 101 according to an embodiment may wirelessly transmit power to a wireless power reception device 195.

While transmitting power to the wireless power reception device 195, the electronic device 101 according to an embodiment may identify the type of the external object (e.g., 181 or 192 of FIG. 1) adjacent to the electronic device 101. The electronic device 101 according to an embodiment may perform an operation of transmitting power to the wireless power reception device 195 and an operation of identifying the type of the external object (e.g., 181 or 192 of FIG. 1) adjacent to the electronic device 101 simultaneously, sequentially, or alternately. For example, the electronic device 101 may identify the type of the external object (e.g., 181 or 192 of FIG. 1) adjacent to the electronic device 101 in a period overlapping at least partly with a period in which power is transmitted to the wireless power reception device 195. According to an embodiment, the electronic device 101 may perform the operation of identifying the type of the external object (e.g., 181 or 192 of FIG. 1) adjacent to the electronic device 101 regardless of the operation of transmitting power to the wireless power reception device 195.

There is no limitation on the type of the wireless power reception device 195. There is no limitation on a method for transmitting power from the electronic device 101 to the wireless power reception device 195. According to an embodiment, the electronic device 101 may, for example, transmit power according to a resonance method. When using the resonant method, the electronic device 101 may include, for example, a power source, a DC-AC conversion circuit, an amplifier circuit, an impedance matching circuit, at least one capacitor, at least one coil, and an out-of-band communication circuit (e.g., a Bluetooth Low Energy (BLE) communication circuit). The at least one capacitor and the at least one coil may form a resonant circuit. The electronic device 101 may be implemented according to a method defined in an Alliance for Wireless Power (A4WP) standard (or, an AirFuel Alliance (AFA) standard). According to an embodiment, the electronic device 101 may, for example, transmit power according to an inductive method. When the electronic device 101 employs the inductive method, the electronic device 101 may include, for example, a power source, a DC-AC conversion circuit, an amplifier circuit, an impedance matching circuit, at least one capacitor, at least one coil, and a communication modulation/demodulation circuit. The at least one capacitor may form a resonant circuit together with the at least one coil. The electronic device 101 may, for example, be implemented according to a method defined in a Wireless Power Consortium (WPC) standard (or Qi standard). The electronic device 101 may include a coil capable of generating an induced magnetic field when a current flows according to the resonance method or the inductive method. A process of the electronic device 101 generating an induced magnetic field may be expressed as the electronic device 101 wirelessly transmitting power. The wireless power reception device 195 may include a coil that generates an induced electromotive force by a magnetic field that is formed around and changes in size according to time. A process of generating an induced electromotive force through the coil may be expressed as the wireless power reception device 195 wirelessly receiving power. For example, the electronic device 101 may be implemented to a method defined in an AirFuel Inductive (e.g., a Power Matters Alliance (PMA)) standard or an AirFuel Resonant (e.g., Rezence) standard as a standard for wireless power transmission or a method defined in the Qi standard. According to an embodiment, the electronic device 101 may transmit power according to an electromagnetic wave method.

In the disclosure, the electronic device 101 performing a specific operation may refer, for example, to various hardware, for example, a control circuit, such as a processor (e.g., a transmission IC and/or a micro-controlling unit (MCU)), and a coil, included in the electronic device 101 performing the specific operation. The electronic device 101 performing a specific operation may may refer, for example, to the processor controlling other hardware to perform the specific operation. The electronic device 101 performing a specific operation may refer, for example, to at least one instruction for performing the specific operation stored in a storage circuit (e.g., a memory) of the electronic device 101 being executed to cause the processor or other hardware to perform the specific operation.

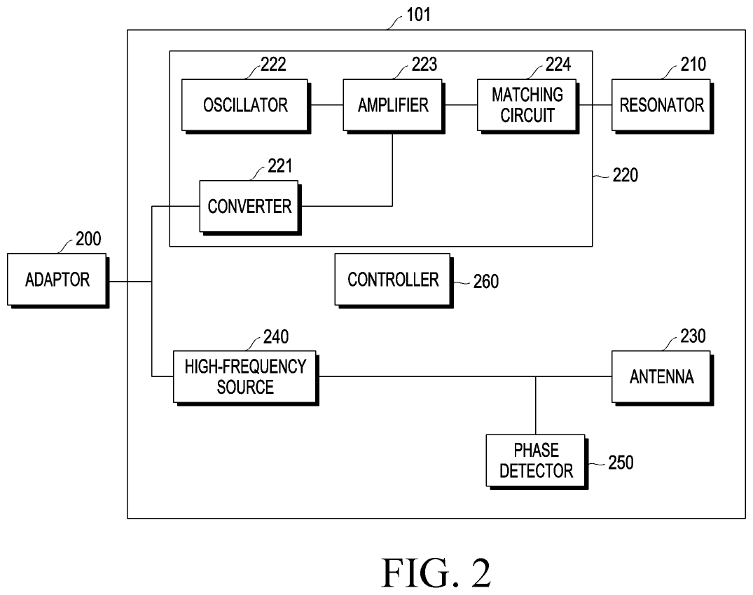

FIG. 2 is a block diagram illustrating an example configuration of an electronic device according to an embodiment.

Referring to FIG. 2, according to an embodiment, an adaptor 200 may convert power (e.g., AC power) provided from an external source (e.g., a wall power source) into power (e.g., DC power) suitable for the electronic device 101. The electronic device 101 may receive the power (e.g., the DC power) converted by the adaptor 200.

According to an embodiment, the electronic device 101 may include at least one of a resonator 210, a power circuit 220, an antenna 230, a high-frequency source 240, a phase detector (e.g., including circuitry) 250, and/or a controller (e.g., including circuitry) 260. For example, the electronic device 101 may include a resonator 210 for wirelessly transmitting power and an antenna 230 for identifying the type of an adjacent object.

According to an embodiment, the electronic device 101 may operate based on power provided through the adaptor 200. For example, the electronic device 101 may wirelessly transmit power to the outside using the resonator 210, based on the power provided through the adaptor 200. For example, the electronic device 101 may identify the type of an object adjacent to the electronic device 101 using the antenna 230, based on the power provided through the adaptor 200.

According to an embodiment, the electronic device 101 may operate based on power inside the electronic device 101 (e.g., power stored in a battery of the electronic device 101). For example, the electronic device 101 may wirelessly transmit power to the outside using the resonator 210, based on the power inside the electronic device 101 (e.g., the power stored in the battery of the electronic device 101). For example, the electronic device 101 may identify the type of an object adjacent to the electronic device 101 using the antenna 230, based on the power inside the electronic device 101 (e.g., the power stored in the battery of the electronic device 101).

According to an embodiment, the power circuit 220 may be configured to provide power to the resonator 210. For example, the electronic device 101 may provide power to the resonator 210 through the power circuit 220, based on the power provided from the adaptor 200. For example, the electronic device 101 may provide power to the resonator 210 through the power circuit 220, based on the power inside the electronic device 101 (e.g., the power stored in the battery of the electronic device 101). The electronic device 101 may wirelessly transmit power to the outside through the resonator 210, based on the power provided from the power circuit 220. For example, the power circuit 220 may include a converter 221, an oscillator 222, an amplifier 223, and a matching circuit 224. The converter 221 may be a DC/DC converter. The converter 221 may include various circuitry and convert power provided to the converter 221, and may provide the converted power to the amplifier 223. For example, the converter 221 may convert the power provided from the adaptor 200, and provide the converted power to the amplifier 223. For example, the converter 221 may convert the power provided from the battery of the electronic device 101, and may provide the converted power to the amplifier 223. The oscillator 222 may output a signal of a first frequency (e.g., a frequency for wireless charging). The oscillator 222 may provide the signal of the first frequency to the amplifier 223. The amplifier 223 may amplify the signal provided from the oscillator 222. The amplifier 223 may output first power having the first frequency, based on the signal of the first frequency provided from the oscillator 222 and the power provided from the converter 221. The matching circuit 224 may perform impedance matching. The electronic device 101 may wirelessly transmit power to the outside through the resonator 210, based on the first power of the first frequency provided from the power circuit 220. The controller 260 may control the power circuit 220 (e.g., at least one of the converter 221, the oscillator 222, the amplifier 223, or the matching circuit 224 included in the power circuit 220) to provide power to the resonator 210. The controller 260 may control the power circuit 220 to provide the first power having the first frequency to the resonator 210.

According to an embodiment, the high-frequency source 240 may be configured to provide power (e.g., a signal) to the antenna 230 (e.g., an input terminal of the antenna 230). For example, the electronic device 101 may provide power (e.g., a signal) to the input terminal of the antenna 230 through the high-frequency source 240, based on the power provided from the adaptor 200. For example, the electronic device 101 may provide power (e.g., a signal) to the input terminal of the antenna 230 through the high-frequency source 240, based on the power inside the electronic device 101 (e.g., the power stored in the battery of the electronic device 101. According to an embodiment, the high-frequency source 240 may include a voltage-controlled oscillator (VCO). For example, the high-frequency source 240 may provide power (e.g., a signal) having a frequency corresponding to the level of an input voltage to the antenna 230, based on the input voltage provided to the high-frequency source 240. The controller 260 may control the frequency of the power provided to the antenna 230 by controlling the high-frequency source 240. For example, the controller 260 may control the high-frequency source 240 to provide second power having a different frequency from the first frequency (e.g., the frequency for wireless charging) to the antenna 230. The electronic device 101 may identify the type of an object adjacent to the electronic device 101 using the antenna 230, based on the power (e.g., the signal) provided from the high-frequency source 240. A method for the electronic device 101 to identify the type of an external object (e.g., 181 or 192 of FIG. 1) will be described later.

According to an embodiment, the electronic device 101 may detect a phase corresponding to the antenna 230 (or the phase of impedance corresponding to the antenna 230) using the phase detector 250. The phase corresponding to the antenna 230 may be a phase identified based on the impedance (e.g., input impedance) of the input terminal of the antenna 230. For example, the electronic device 101 may identify the phase corresponding to the antenna 230, based on the impedance of the input terminal of the antenna 230 as power (e.g., a signal) is applied from the high-frequency source 240 to the antenna 230. For example, the electronic device 101 may identify a voltage and a current, based on a reference signal input to the antenna 230 and a reflected signal of the input terminal of the antenna 230, and detect the phase of the impedance of the antenna 230, based on the identified voltage and current, thereby detecting the phase of the impedance corresponding to the antenna 230.

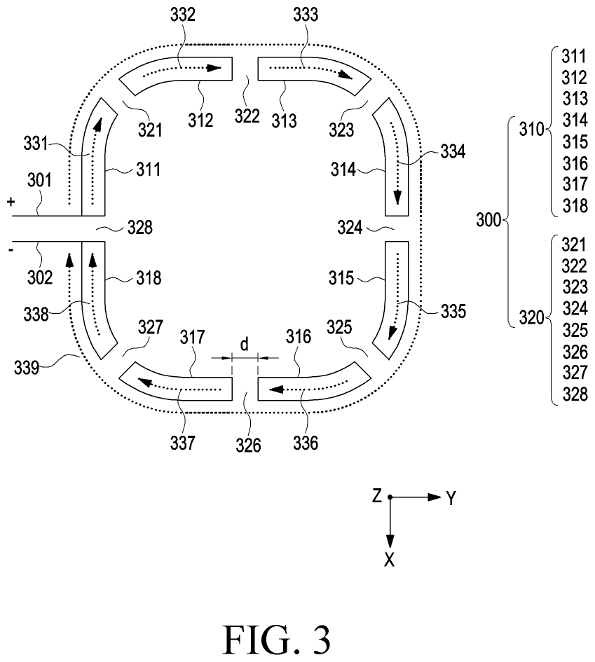

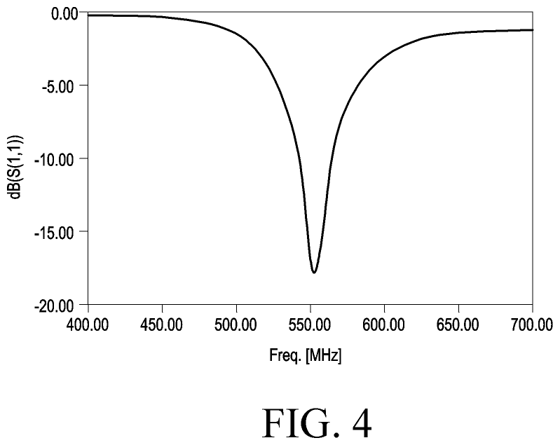

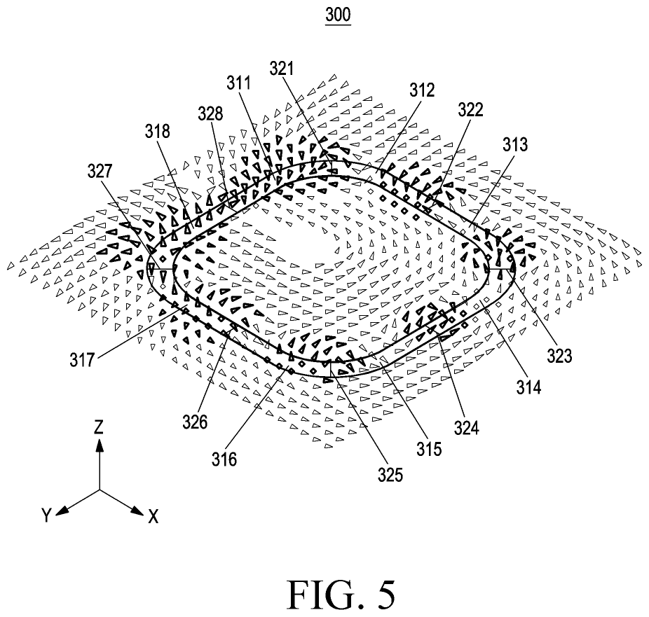

FIG. 3 is a diagram illustrating an example structure of an antenna according to an embodiment. FIG. 3 may be explained with reference to FIG. 4 and FIG. 5. FIG. 4 is a graph illustrating the operating frequency of an antenna according to an embodiment. FIG. 5 is a diagram illustrating an electric field around an antenna according to an embodiment.

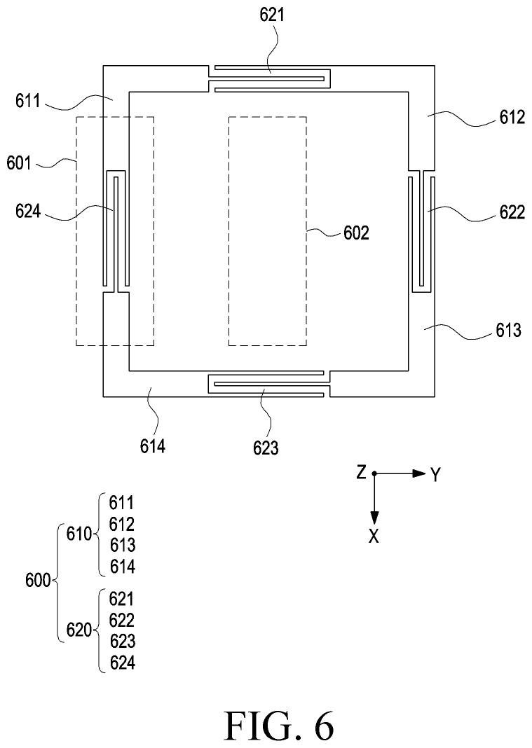

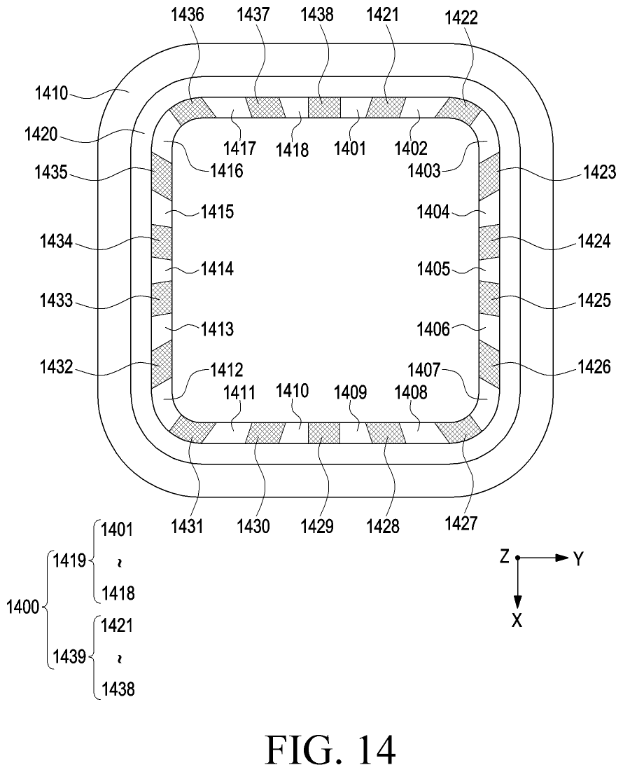

The antenna 230 of FIG. 2 may be a zeroth-order resonance (ZOR) antenna. The ZOR antenna may be an antenna in which a current in the same direction is formed by power provided to the antenna. The “current in the same direction” will be described later. The ZOR antenna may be a ring-shaped antenna including a plurality of sub-antennas. There is no limitation on the shape of the ZOR antenna. The ZOR antenna may be understood with reference to the embodiment of FIG. 3. A description of ZOR antennas of embodiments of FIG. 6 and FIG. 14 overlapping with a description of the ZOR antenna of FIG. 3 may not be provided here.

Referring to FIG. 3, according to an embodiment, the electronic device 101 may include a first antenna 300. The first antenna 300 may be a ZOR antenna. The first antenna 300 of FIG. 3 may be an example of the antenna 230 of FIG. 2.

Referring to FIG. 3, the first antenna 300 may include a plurality of sub-antennas 310. Although there is no limitation on the number of sub-antennas 310 included in the first antenna 300, FIG. 3 shows a case in which eight sub-antennas are included. For example, the first antenna 300 may include a first sub-antenna 311, a second sub-antenna 312, a third sub-antenna 313, a fourth sub-antenna 314, a fifth sub-antenna 315, a sixth sub-antenna 316, a seventh sub-antenna 317, and an eighth sub-antenna 318. The first antenna 300 may include a plurality of dividing parts 320 between the plurality of sub-antennas 310. For example, the first antenna 300 may include a first dividing part 321 between the first sub-antenna 311 and the second sub-antenna 312, a second dividing part 322 between the second sub-antenna 312 and the third sub-antenna 313, a third dividing part 323 between the third sub-antenna 313 and the fourth sub-antenna 314, a fourth dividing part 324 between the fourth sub-antenna 314 and the fifth sub-antenna 315, a fifth dividing part 325 between the fifth sub-antenna 315 and the sixth sub-antenna 316, a sixth dividing part 326 between the sixth sub-antenna 316 and the seventh sub-antenna 317, a seventh dividing part 327 between the seventh sub-antenna 317 and the eighth sub-antenna 318, and an eighth dividing part 328 between the eighth sub-antenna 318 and the first sub-antenna 311. The plurality of dividing parts 320 may operate as capacitors. For example, an antenna (e.g., the first antenna 300) including a plurality of dividing parts (e.g., the plurality of dividing parts 320) may be expressed as the antenna (e.g., the first antenna 300) including a plurality of capacitors. According to an embodiment, the first antenna 300 may include a plurality of dielectrics positioned in the plurality of dividing parts 320. The width (e.g., d in FIG. 3) of the plurality of dividing parts 320 may be determined depending on the design of the first antenna 300.

According to an embodiment, the first antenna 300 may receive power (e.g., a signal) through input terminals 301 and 302. The first antenna 300 may receive power (e.g., AC power) provided from the high-frequency source 240 through the input terminals 301 and 302. As the power provided from the high-frequency source 240 is applied to the input terminals 301 and 302 of the first antenna 300, currents in the same direction may be generated in the first antenna 300 (e.g., the plurality of sub-antennas 310 included in the first antenna 300). For example, as the AC power is applied to the input terminals 301 and 302 of the first antenna 300, a current may be generated in the plurality of sub-antennas 310 included in the first antenna 300 respectively. As the AC power is applied, even though the directions of currents formed respectively in the plurality of sub-antennas 310 change depending on a time point, when the directions of currents formed respectively in the plurality of sub-antennas 310 at the same time point are the same, it may be considered that currents in the same direction are generated in the first antenna 300. For example, in FIG. 3, as the power provided from the high-frequency source 240 is applied to the input terminals 301 and 302 of the first antenna 300, when a current in a first direction 331 is generated in the first sub-antenna 311, a current in a second direction 332 is generated in the second sub-antenna 312, a current in a third direction 333 is generated in the third sub-antenna 313, a current in a fourth direction 334 is generated in the fourth sub-antenna 314, a current in a fifth direction 335 is generated in the fifth sub-antenna 315, a current in a sixth direction 336 is generated in the sixth sub-antenna 316, a current in a seventh direction 337 is generated in the seventh sub-antenna 317, and a current in an eighth direction 338 is generated in the eighth sub-antenna 318 at a first time point, if the first direction 331, the second direction 332, the third direction 333, the fourth direction 334, the fifth direction 335, the sixth direction 336, the seventh direction 337, and the eighth direction 338 form one direction 339 (e.g., a clockwise direction), it may be considered that currents in the same direction are generated in the first antenna 300. Subsequently, at a second time point, when a current in the opposite direction of the first direction 331 is formed in the first sub-antenna 311, currents in the opposite directions of the directions of the currents formed at the first time point may also be formed in the second sub-antenna 312, the third sub-antenna 313, the fourth sub-antenna 314, the fifth sub-antenna 315, the sixth sub-antenna 316, the seventh sub-antenna 317, and the eighth sub-antenna 318. As described above, as AC power is applied to input terminals (e.g., the input terminals 301 and 302) of an antenna (e.g., the first antenna 300), when currents in the same direction are generated in a plurality of sub-antennas (e.g., the plurality of sub-antennas 310) included in the antenna (e.g., the first antenna 300), the antenna (e.g., the first antenna 300) may be referred to as a ZOR antenna.

FIG. 4 is a graph illustrating the reflection coefficient of the first antenna 300 of FIG. 3. Referring to FIG. 4, the operating frequency (e.g., a frequency near 550 MHz) of the first antenna 300 of FIG. 3 may be identified. FIG. 5 illustrates an electric field generated by currents in the same direction formed in the first antenna 300 of FIG. 3. Referring to FIG. 5, it may be identified that a uniform electric field is formed around the first antenna 300 as power having the operating frequency of FIG. 4 is applied to the first antenna 300 of FIG. 3. The uniform electric field may be an electric field of which the distribution is symmetrical. For example, in FIG. 5, the distribution of the electric field around the first antenna 300 may be symmetrical with respect to the center of the first antenna 300.

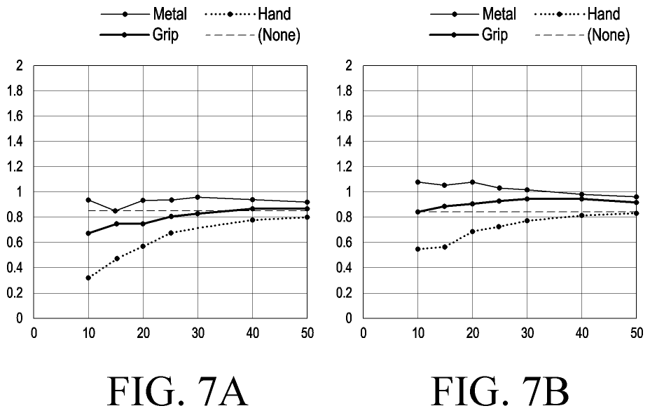

FIG. 6 is a diagram illustrating an example structure of an antenna according to an embodiment. FIG. 6 may be explained with reference to FIGS. 7A and 7B. FIGS. 7A and 7B are graphs illustrating an example operation of an electronic device according to an embodiment.

Referring to FIG. 6, according to an embodiment, the electronic device 101 may include a second antenna 600. The second antenna 600 may be a ZOR antenna. The second antenna 600 of FIG. 6 may be an example of the antenna 230 of FIG. 2. An antenna including an interdigital capacitor structure may be understood with reference to the second antenna 600 of FIG. 6. The interdigital capacitor structure may be a structure in which ends of conductors forming capacitors are interlocked with each other. Although FIG. 6 shows that ends of conductors forming capacitors are interlocked with each other once, which is for illustration, there is no limitation on the interlocking arrangement structure.

Referring to FIG. 6, the second antenna 600 may include a plurality of sub-antennas 610. Although there is no limitation on the number of sub-antennas 610 included in the second antenna 600, FIG. 6 shows a case in which four sub-antennas are included. For example, the second antenna 600 may include a first sub-antenna 611, a second sub-antenna 612, a third sub-antenna 613, and a fourth sub-antenna 614. The first sub-antenna 611, the second sub-antenna 612, the third sub-antenna 613, and the fourth sub-antenna 614 may form an interdigital capacitor structure. The second antenna 600 may include a plurality of dividing parts 620 between the plurality of sub-antennas 610. For example, a first dividing part 621 between the first sub-antenna 611 and the second sub-antenna 612 may operate as a first interdigital capacitor. A second dividing part 622 between the second sub-antenna 612 and the third sub-antenna 613 may operate as a second interdigital capacitor. A third dividing part 623 between the third sub-antenna 613 and the fourth sub-antenna 614 may operate as a third interdigital capacitor. A fourth dividing part 624 between the fourth sub-antenna 614 and the first sub-antenna 611 may operate as a fourth interdigital capacitor. As power (e.g., AC power) provided from the high-frequency source 240 is applied to an input terminal of the second antenna 600, currents in the same direction may be generated in the second antenna 600 (e.g., the plurality of sub-antennas 610 included in the second antenna 600).

FIGS. 7A and 7B are graphs according to the distance between the second antenna 600 and an external object (e.g., 181 or 192 of FIG. 1) while currents in the same direction are formed in the second antenna 600 as power (e.g., AC power having the operating frequency of the second antenna 600) provided from the high-frequency source 240 is applied to the input terminal of the second antenna 600 of FIG. 6.

FIG. 7A is a graph when the object moves in a z-axis direction in a first area 601 of FIG. 6, and FIG. 7B is a graph when the object moves in the z-axis direction in a second area 602 of FIG. 6. The horizontal axis of the graphs of (a) and (b) of FIG. 7 denotes the distance (e.g., [cm]) from the electronic device 101 to the object, and the vertical axis denotes a voltage (e.g., [V]) corresponding to the phase of the second antenna 600. The electronic device 101 (e.g., the controller 260) may identify the voltage corresponding to the phase of the second antenna 600 using the phase detector 250. FIGS. 7A and 7B are graphs corresponding to the second antenna 600 of FIG. 6, but a graph corresponding to the first antenna 300 of FIG. 3 may also be similar to the graph of FIGS. 7A and 7B. In FIG. 7A, “None” shows a case where there is no object in the first area 601, “Metal” shows a case where metal exists in the first area 601, “Hand” shows a case where a human body (e.g., a hand) exists in the first area 601, and “Grip” shows a case where metal gripped by a human body (e.g., a hand) exists in the first area 601. FIG. 7B may be understood similarly.

FIGS. 7A and 7B show that the voltage corresponding to the phase of the second antenna 600 changes similarly when an object (e.g., a conductor or a human body) moves in the z-axis direction in the first area 601 of the second antenna 600 and when the object (e.g., the conductor or the human body) moves in the z-axis direction in the second area 602 of the second antenna 600. For example, referring to FIGS. 7A and 7B, in a case where the object adjacent to the second antenna 600 approaches the second antenna 600 and the object is a conductor (e.g., “Metal” in FIGS. 7A and 7B), it may be identified that the voltage corresponding to the phase of the second antenna 600 gradually increases compared to a case where there is no object adjacent to the second antenna 600. For example, referring to FIGS. 7A and 7B, in a case where the object adjacent to the second antenna 600 approaches the second antenna 600 and the object is a conductor (e.g., “Hand” in FIGS. 7A and 7B), it may be identified that the voltage corresponding to the phase of the second antenna 600 gradually decrease compared to a case where there is no object adjacent to the second antenna 600. Accordingly, the electronic device 101 may identify the phase of the second antenna 600 (or the voltage corresponding to the phase of the second antenna 600), thereby identifying the type of the object (e.g., the conductor or the human body) adjacent to the second antenna 600.

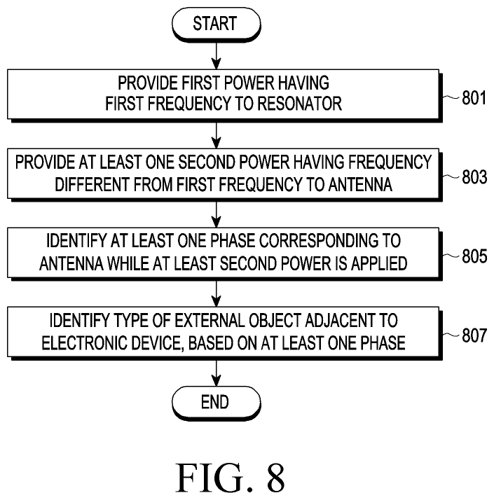

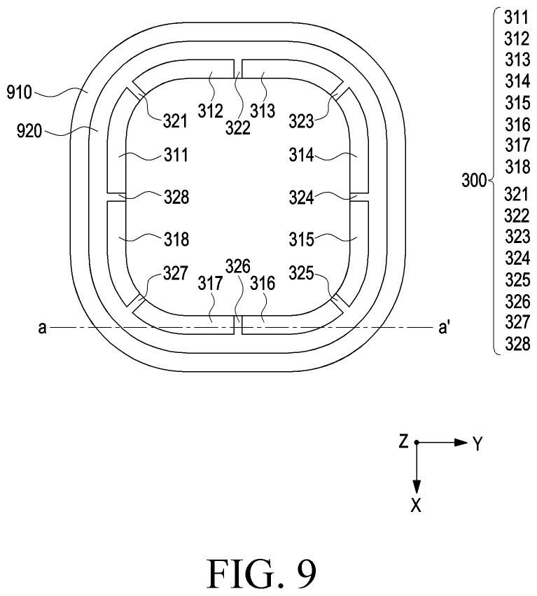

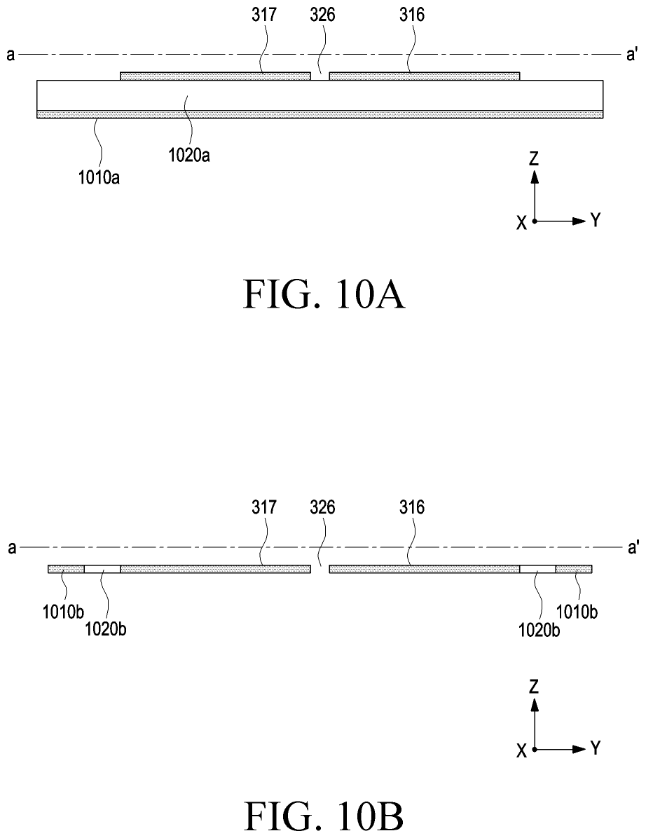

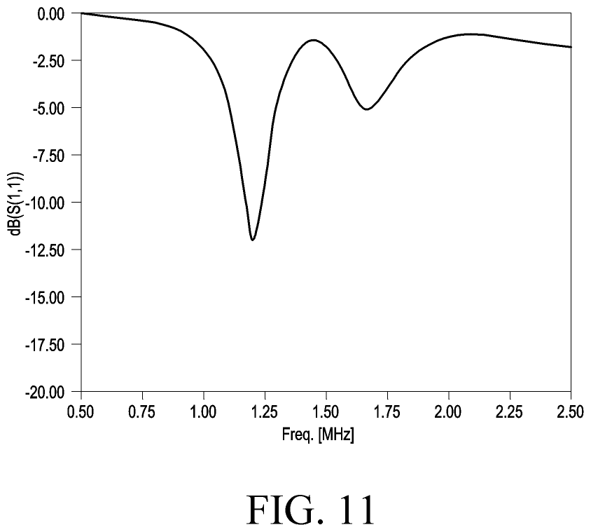

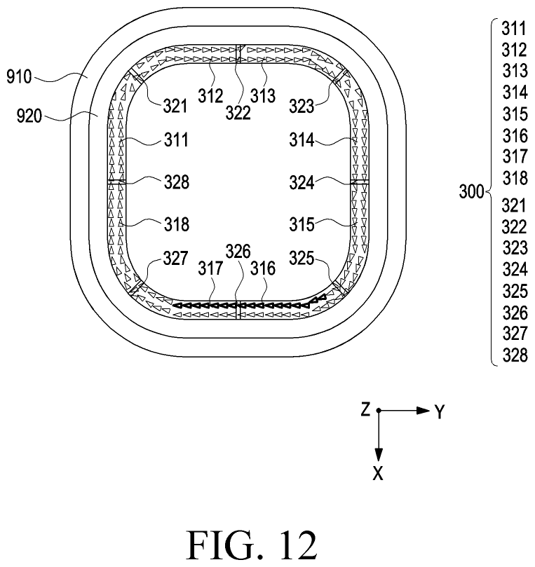

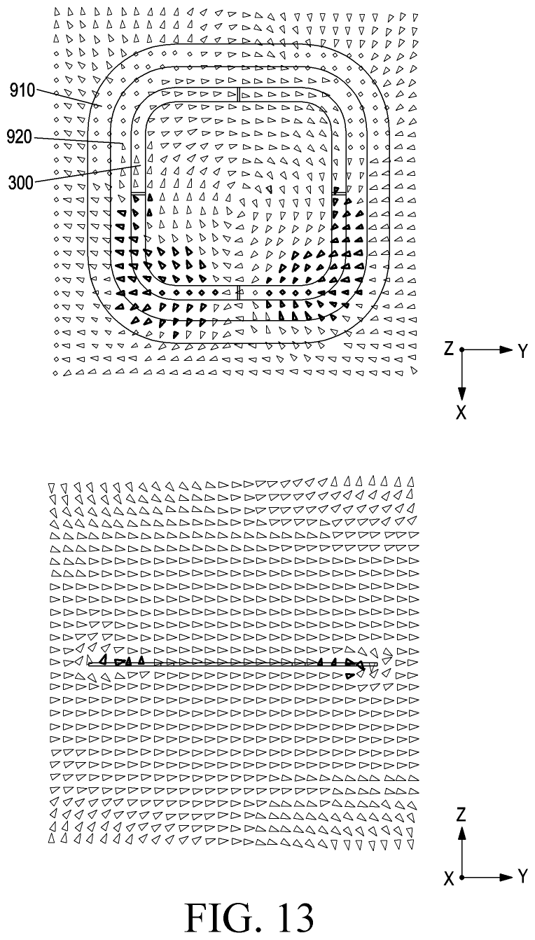

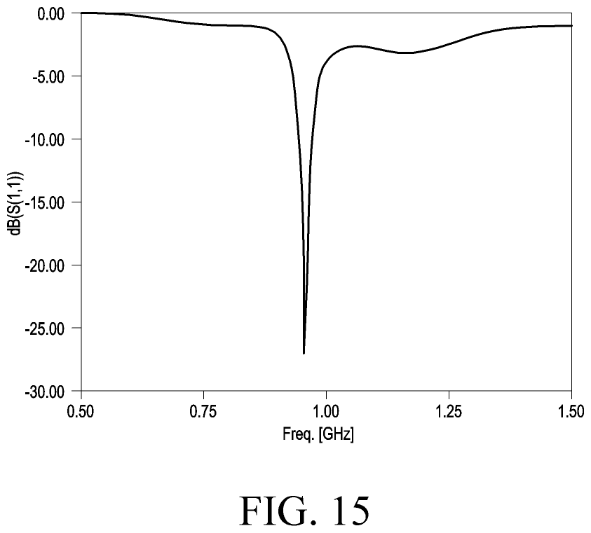

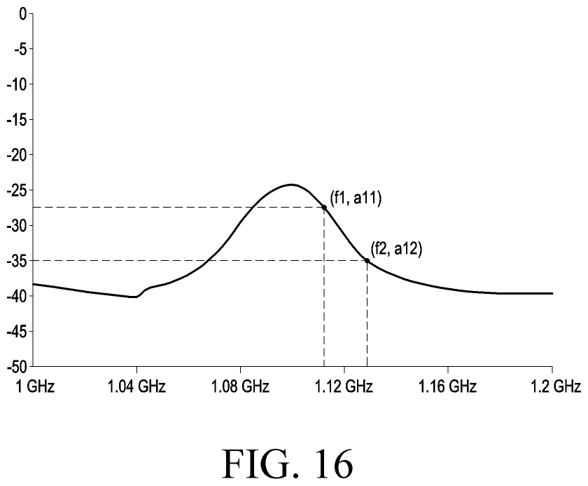

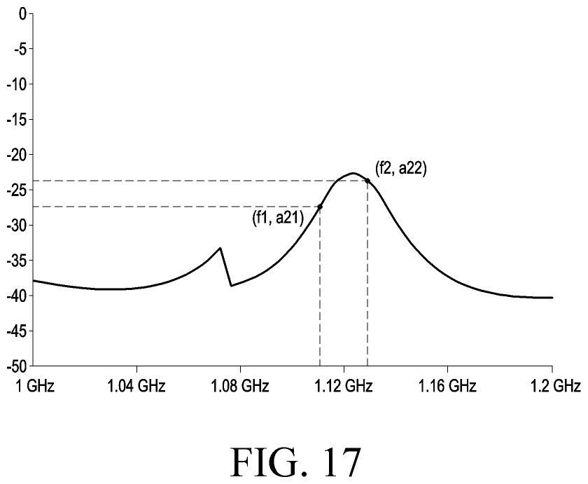

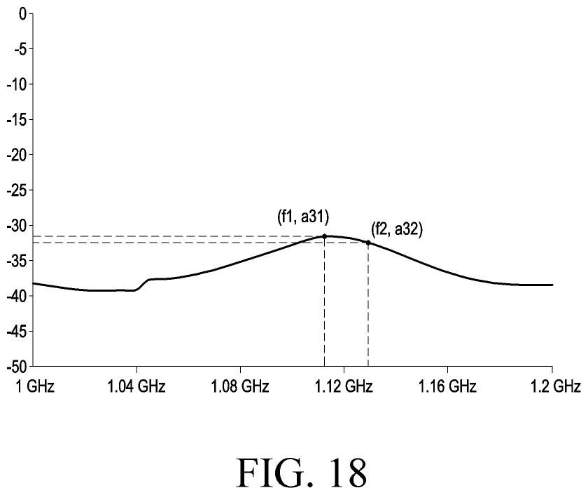

FIG. 8 is a flowchart illustrating an example operation of an electronic device according to an embodiment. FIG. 8 may be explained with reference to FIG. 9, FIG. 10A, FIG. 10B, FIG. 11, FIG. 12, FIG. 13, FIG. 14, FIG. 15, FIG. 16, FIG. 17, and FIG. 18. FIG. 9 is a diagram illustrating an example resonator and an antenna according to an embodiment. FIG. 10A is a cross-sectional view illustrating a resonator and an antenna according to an embodiment. FIG. 10B is a cross-sectional view illustrating a resonator and an antenna according to an embodiment. FIG. 11 is a graph illustrating the operating frequency of an antenna according to an embodiment. FIG. 12 is a diagram illustrating the flow of a current in an antenna according to an embodiment. FIG. 13 is a diagram illustrating an electric field around an antenna according to an embodiment. FIG. 14 is a diagram illustrating an example structure of an antenna according to an embodiment. FIG. 15 is a graph illustrating the operating frequency of an antenna according to an embodiment. FIG. 16 is a graph illustrating an example operation of an electronic device according to an embodiment. FIG. 17 is a graph illustrating an example operation of an electronic device according to an embodiment. FIG. 18 is a graph illustrating an example operation of an electronic device according to an embodiment.

The arrangement of the antenna 230 and the resonator 210 included in an electronic device 101 may be described with reference to FIG. 9. A first antenna 300 of FIG. 9 may be the first antenna 300 of FIG. 3 (e.g., the antenna 230 of FIG. 2). A resonator 910 of FIG. 9 may be the resonator 210 of FIG. 2.

According to an embodiment, the electronic device 101 may include the resonator 910 and the first antenna 300 disposed in an inner area of the resonator 910. The first antenna 300 being disposed in the inner area of the resonator 910 may refer, for example, to, when viewed from above (e.g., in the z-axis direction of FIG. 9), a ring-shaped area formed by the first antenna 300 being positioned in an inner area of a ring-shaped area formed by the resonator 910. As shown in FIG. 9, when viewed in the z-axis direction, at least a portion of an inner area of the first antenna 300 may be an empty space. Accordingly, a ring shape of the electronic device 101 of FIG. 1 may be realized. The overall form of the first antenna 300 disposed in the inner area of the resonator 910 may correspond to the form of the resonator 910. The corresponding forms may refer, for example, to corresponding shapes. When the forms have different sizes but have correspond shapes, the forms may be expressed as corresponding. For example, referring to FIG. 9, both the resonator 910 and the first antenna 300 may be formed in a ring shape.

According to an embodiment, the electronic device 101 may include a dielectric 920 between the resonator 910 and the first antenna 300. The structure of a cross-section a-a′ of FIG. 9 viewed in an x-axis direction is described with reference to FIG. 10A and FIG. 10B. FIG. 10A illustrates an example of the arrangement of the resonator 910 (e.g., a resonator 1010a), the dielectric 920 (e.g., a dielectric 1020a), and the first antenna 300. FIG. 10B illustrates another example of the arrangement of the resonator 910 (e.g., a resonator 1010b), the dielectric 920 (e.g., 1020b), and the first antenna 300. Referring to FIG. 10A, the dielectric 1020a may be disposed on the resonator 1010a, and the first antenna 300 may be disposed on the dielectric 1020a. Although FIG. 9 shows that the dielectric 920 is positioned in the inner area of the resonator 910, which is for convenience of explanation, the dielectric 920 (e.g., the dielectric 1020a) may be formed with an area corresponding to the resonator 910 as in FIG. 10A. Referring to FIG. 10B, the resonator 1010b, the dielectric 1020b, and the first antenna 300 may be formed on one plane. For example, as shown in FIG. 10B, the dielectric 1020b may be disposed to surround the first antenna 300, and the resonator 1010b may be disposed to surround the dielectric 1020b. According to an embodiment, another component may be disposed among the resonator 910 (e.g., the resonator 1010a or the resonator 1010b), the dielectric 920 (e.g., the dielectric 1020a or the dielectric 1020b), and the first antenna 300. The arrangement of a resonator 1410, a dielectric 1420, and a third antenna 1400 of FIG. 14 to be described below may also correspond to the arrangement of FIG. 10A or FIG. 10B.

FIG. 11 is a graph illustrating the reflection coefficient of the first antenna 300 of FIG. 9. Referring to FIG. 11, the operating frequency (e.g., a frequency near 1.2 GHz) of the first antenna 300 disposed in the inner area of the resonator 910 of FIG. 9 may be identified. FIG. 12 is a diagram illustrating that currents in the same direction are formed in the first antenna 300 disposed in the inner area of the resonator 910 of FIG. 9. Referring to FIG. 12, when power having the operating frequency of FIG. 11 is applied to the first antenna 300 disposed in the inner area of the resonator 910 of FIG. 9, currents in the same direction may be formed in the first antenna 300. FIG. 13 illustrates an electric field generated by currents in the same direction formed in the first antenna 300 of FIG. 9. Referring to FIG. 13, it may be identified that a uniform electric field is formed around the first antenna 300 as power having the operating frequency of FIG. 11 is applied to the first antenna 300 disposed in the inner area of the resonator 910 of FIG. 9.

Referring to FIG. 14, according to an embodiment, the electronic device 101 may include a third antenna 1400. The third antenna 1400 may be a ZOR antenna. The third antenna 1400 of FIG. 14 may be an example of the antenna 230 of FIG. 2.

Referring to FIG. 14, the third antenna 1400 may include a plurality of sub-antennas 1419. Although there is no limitation on the number of sub-antennas 1419 included in the third antenna 1400, FIG. 14 shows a case in which 18 sub-antennas are included. For example, the third antenna 1400 may include a first sub-antenna 1401, a second sub-antenna 1402, a third sub-antenna 1403, a fourth sub-antenna 1404, a fifth sub-antenna 1405, a sixth sub-antenna 1406, a seventh sub-antenna 1407, an eighth sub-antenna 1408, a ninth sub-antenna 1409, a tenth sub-antenna 1410, an eleventh sub-antenna 1411, a twelfth sub-antenna 1412, a thirteenth sub-antenna 1413, a fourteenth sub-antenna 1414, a fifteenth sub-antenna 1415, a sixteenth sub-antenna 1416, a seventeenth sub-antenna 1417, and an eighteenth sub-antenna 1418. The first sub-antenna 1401, the second sub-antenna 1402, the third sub-antenna 1403, the fourth sub-antenna 1404, the fifth sub-antenna 1405, the sixth sub-antenna 1406, the seventh sub-antenna 1407, the eighth sub-antenna 1408, the ninth sub-antenna 1409, the tenth sub-antenna 1410, the eleventh sub-antenna 1411, the twelfth sub-antenna 1412, the thirteenth sub-antenna 1413, the fourteenth sub-antenna 1414, the fifteenth sub-antenna 1415, the sixteenth sub-antenna 1416, the seventeenth sub-antenna 1417, and the eighteenth sub-antenna 1418 may form an interdigital capacitor structure. The third antenna 1400 may include a plurality of dividing parts 1439 between the plurality of sub-antennas 1419. For example, a first dividing part 1421 between the first sub-antenna 1401 and the second sub-antenna 1402 may operate as a first interdigital capacitor. A second dividing part 1422 between the second sub-antenna 1402 and the third sub-antenna 1403 may operate as a second interdigital capacitor. A third dividing part 1423 between the third sub-antenna 1403 and the fourth sub-antenna 1404 may operate as a third interdigital capacitor. A fourth dividing part 1424 between the fourth sub-antenna 1404 and the fifth sub-antenna 1405 may operate as a fourth interdigital capacitor. A fifth dividing part 1425 between the fifth sub-antenna 1405 and the sixth sub-antenna 1406 may operate as a fifth interdigital capacitor. A sixth dividing part 1426 between the sixth sub-antenna 1406 and the seventh sub-antenna 1407 may operate as a sixth interdigital capacitor. A seventh dividing part 1427 between the seventh sub-antenna 1407 and the eighth sub-antenna 1408 may operate as a seventh interdigital capacitor. An eighth dividing part 1428 between the eighth sub-antenna 1408 and the ninth sub-antenna 1409 may operate as an eighth interdigital capacitor. A ninth dividing part 1429 between the ninth sub-antenna 1409 and the tenth sub-antenna 1410 may operate as a ninth interdigital capacitor. A tenth dividing part 1430 between the tenth sub-antenna 1410 and the eleventh sub-antenna 1411 may operate as a tenth interdigital capacitor. An eleventh dividing part 1431 between the eleventh sub-antenna 1411 and the twelfth sub-antenna 1412 may operate as an eleventh interdigital capacitor. A twelfth dividing part 1432 between the twelfth sub-antenna 1412 and the 13th sub-antenna 1413 may operate as a twelfth interdigital capacitor. A thirteenth dividing part 1433 between the thirteenth sub-antenna 1413 and the fourteenth sub-antenna 1414 may operate as a thirteenth interdigital capacitor. A fourteenth dividing part 1434 between the fourteenth sub-antenna 1414 and the fifteenth sub-antenna 1415 may operate as a fourteenth interdigital capacitor. A fifteenth dividing part 1435 between the fifteenth sub-antenna 1415 and the sixteenth sub-antenna 1416 may operate as a fifteenth interdigital capacitor. A sixteenth dividing part 1436 between the sixteenth sub-antenna 1416 and the seventeenth sub-antenna 1417 may operate as a sixteenth interdigital capacitor. A seventeenth dividing part 1437 between the seventeenth sub-antenna 1417 and the eighteenth sub-antenna 1418 may operate as a seventeenth interdigital capacitor. An eighteenth dividing part 1438 between the eighteenth sub-antenna 1418 and the first sub-antenna 1401 may operate as an eighteenth interdigital capacitor. When power (e.g., AC power) provided from the high-frequency source 240 is applied to an input terminal of the third antenna 1400, currents in the same direction may be generated in the third antenna 1400 (e.g., the plurality of sub-antennas 1419 included in the third antenna 1400). According to an embodiment, the third antenna 1400 may include a plurality of dielectrics disposed in the plurality of dividing parts 1439).

The arrangement of the antenna 230 and the resonator 210 included in the electronic device 101 may be described with reference to FIG. 14. The third antenna 1400 of FIG. 14 may be an example of the antenna 230 of FIG. 2. A resonator 1410 of FIG. 14 may be the resonator 210 of FIG. 2. FIG. 14 shows that the inside first antenna 300 of FIG. 9 is replaced with the third antenna 1400.

Referring to FIG. 14, according to an embodiment, the electronic device 101 may include the resonator 1410 and the third antenna 1400 disposed in an inner area of the resonator 1410. The arrangement of FIG. 14 may be similar to the arrangement of FIG. 9. The arrangement of the resonator 1410, a dielectric 1420, and the third antenna 1400 of FIG. 14 may be similar to the arrangement of FIG. 10A or FIG. 10B. The overall form of the third antenna 1400 disposed in the inner area of the resonator 1410 may correspond to the form of the resonator 1410. For example, referring to FIG. 14, both the resonator 1410 and the third antenna 1400 may be formed in a ring shape. FIG. 15 is a graph illustrating the reflection coefficient of the third antenna 1400 of FIG. 14. Referring to FIG. 15, the operating frequency (e.g., a frequency near 0.95 GHz) of the third antenna 1400 disposed in the inner area of the resonator 1410 of FIG. 14 may be identified. Referring to FIG. 15 and FIG. 11, the operating frequency of the third antenna 1400 of FIG. 14 may be lower than the operating frequency of the first antenna 300 of FIG. 9.

Operations of FIG. 8 may be applied to the examples of FIG. 9 and FIG. 14. The operations of FIG. 8 will be described with reference to reference numerals of FIG. 2 for convenience of explanation, but those skilled in the art will understand that the example of FIG. 8 may be applied to components of FIG. 9 or FIG. 14 corresponding to the reference numerals of FIG. 2.

At least some of the operations of FIG. 8 may be omitted. The operations of FIG. 8 may be performed in a different order. Operations other than the operations of FIG. 8 may be performed before, during, or after the operations of FIG. 8.

Referring to FIG. 8, in operation 801, according to an embodiment, the electronic device 101 (e.g., the controller 260) may provide first power having a first frequency to the resonator 210 (e.g., 910 of FIG. 9 or 1410 of FIG. 14). The electronic device 101 may control the power circuit 220 to provide the first power having the first frequency (e.g., a frequency for wireless charging) to the resonator 210 (e.g., 910 or 1410). The electronic device 101 may wirelessly transmit power to the outside through the resonator 210 (e.g., 910 or 1410), based on the first power having the first frequency.

In operation 803, according to an embodiment, the electronic device 101 (e.g., the controller 260) may provide at least one second power having a frequency different from the first frequency (e.g., the frequency for wireless charging) to the antenna 230 (e.g., 300 of FIG. 9 or 1400 of FIG. 14). The electronic device 101 may control the high-frequency source 240 to provide the at least one second power having the frequency different from the first frequency (e.g., the frequency for wireless charging) to the antenna 230. “At least one second power” refers to power having a different frequency from the first frequency (e.g., the frequency for wireless charging) provided to the antenna 230, and may be power of one frequency or be a plurality of powers having different frequencies. For example, the electronic device 101 may provide power to the antenna 230 while changing the frequency of the power provided to the antenna 230. For example, in a case where power having a second frequency is provided to the antenna 230 at a first time point, the case may be expressed as at least one second power being applied to the antenna 230. For example, in a case where power having a third frequency is provided to the antenna 230 at a second time point and power having a fourth frequency is provided to the antenna 230 at a third time point, the case may be expressed as at least one second power being applied to the antenna 230. The electronic device 101 may perform operation 803 (or operation 803, operation 805, and operation 807) in a period overlapping at least partly with a period in which operation 801 is performed.

In operation 805, according to an embodiment, the electronic device 101 (e.g., the controller 260) may identify at least one phase of impedance corresponding to the antenna 230 (e.g., 300 of FIG. 9 or 1400 of FIG. 14) while the at least one second power having the different frequency from the first frequency (e.g., the frequency for wireless charging) is applied to the antenna 230 (e.g., 300 of FIG. 9 or 1400 of FIG. 14). The at least one phase may be the phase of impedance corresponding to the antenna 230 (e.g., 300 of FIG. 9 or 1400 of FIG. 14) while the at least one second power is applied. For example, when the power having the second frequency is provided to the antenna 230, the electronic device 101 may identify at least one phase of impedance corresponding to the antenna 230 while the power having the second frequency is provided to the antenna 230. For example, when the power having the third frequency and the power having the fourth frequency are alternately provided to the antenna 230, the electronic device 101 may identify at least one phase of impedance corresponding to the antenna 230 while the power having the third frequency is provided to the antenna 230, and may identify at least one phase of impedance corresponding to the antenna 230 while the power having the fourth frequency is provided to the antenna 230.

In operation 807, according to an embodiment, the electronic device 101 (e.g., the controller 260) may identify the type of an external object (e.g., 181 or 192 of FIG. 1) adjacent to the electronic device 101, based on the at least one phase identified in operation 805.

Operation 807 is described with reference to FIG. 16, FIG. 17, and FIG. 18.

FIG. 16 is a graph illustrating when no object exists around the electronic device 101. FIG. 17 is a graph illustrating when an object of a first type (e.g., a conductor) exists around the electronic device 101. FIG. 18 is a graph illustrating when an object of a second type (e.g., a human body) exists around the electronic device 101. In FIG. 16, FIG. 17, and FIG. 18, the horizontal axis denotes the frequency of power provided to the antenna 230, and the vertical axis denotes the phase of impedance corresponding to the antenna 230. The levels of the frequencies and phases in FIG. 16, FIG. 17, and FIG. 18 are for illustration, and may be different depending on implementation methods and specifications of the antenna 230.

In FIG. 16, FIG. 17, and FIG. 18, the terms “first frequency” and “second frequency” are used to explain that powers of different frequencies are provided to the antenna 230. A first frequency and a second frequency in FIG. 16, FIG. 17, and FIG. 18 are frequencies different from the first frequency in operation 801 (e.g., the frequency for wireless charging).

In FIG. 16, in a case where no object exists around the electronic device 101, when power of the first frequency f1 is applied to the antenna 230, the phase of impedance corresponding to the antenna 230 may be a11 (e.g., −27 degrees). For example, FIG. 16 shows that when no object exists around the electronic device 101, the electronic device 101 may identify the phase of the impedance corresponding to the antenna 230 while the power of the first frequency f1 is applied to the antenna 230, and the phase may be a11 (e.g., −27 degrees). A similar description is omitted. In FIG. 16, in the case where no object exists around the electronic device 101, when power of the second frequency f2 is applied to the antenna 230, the phase of impedance corresponding to the antenna 230 may be a12 (e.g., −35 degrees).

In FIG. 17, in a case where the object of the first type (e.g., the conductor) exists around the electronic device 101, when the power of the first frequency (f1) is applied to the antenna 230, the phase of impedance corresponding to the antenna 230 may be a21 (e.g., −27 degrees). a21 in FIG. 17 may be almost similar to a11 in FIG. 16. In FIG. 17, in the case where the object of the first type (e.g., the conductor) exists around the electronic device 101, when the power of the second frequency f2 is applied to the antenna 230, the phase of impedance corresponding to the antenna 230 may be a22 (e.g., −24 degrees).

In FIG. 18, in a case where the object of the second type (e.g., the human body) exists around the electronic device 101, when the power of the first frequency f1 is applied to the antenna 230, the phase of impedance corresponding to the antenna 230 may be a31 (e.g., −32 degrees). In FIG. 18, in the case where the object of the second type (e.g., the human body) exists around the electronic device 101, when the power of the second frequency f2 is applied to the antenna 230, the phase of impedance corresponding to the antenna 230 may be a32 (e.g., −33 degrees).

According to an embodiment, referring to FIG. 16, FIG. 17, and FIG. 18, the electronic device 101 (e.g., the controller 260) may identify at least one phase of the impedance corresponding to the antenna 230 while the power of the first frequency f1 is applied to the antenna 230. Here, the electronic device 101 may identify the type of the external object (e.g., 181 or 192 of FIG. 1) adjacent to the electronic device 101, based on the identified at least one phase of the impedance corresponding to the antenna 230. For example, as the phase of the impedance corresponding to the antenna 230 decreases from a first phase (e.g., a11 of FIG. 16) to a second phase (e.g., a31 of FIG. 18) which is smaller by a specified level or more than the first phase (e.g., a11 of FIG. 16) while the power of the first frequency f1 is applied to the antenna 230, the electronic device 101 may detect that the object of the second type (e.g., the human body) is approaching the electronic device 101. For example, after the electronic device 101 identifies that the external object approaches the electronic device 101, as the phase of the impedance corresponding to the antenna 230 is maintained in a designated range including the first phase (e.g., a11 of FIG. 16) while the power of the first frequency f1 is applied to the antenna 230, the electronic device 101 may identify that the object of the first type (e.g., the conductor) is approaching the electronic device 101.

According to an embodiment, referring to FIG. 16, FIG. 17, and FIG. 18, the electronic device 101 (e.g., the controller 260) may alternately apply the power of the first frequency f1 and the power of the second frequency f2 to the antenna 230. The electronic device 101 may alternately and continuously apply the power of the first frequency f1 and the power of the second frequency f2 to the antenna 230. The electronic device 101 may identify the type of the external object (e.g., 181 or 192 of FIG. 1) adjacent to the electronic device 101, based on at least one phase identified while applying the power of the first frequency f1 to the antenna 230 and at least one phase identified while applying the power of the second frequency f2 to the antenna 230. For example, as the phase of the impedance corresponding to the antenna 230 is maintained in the designated range including the first phase (e.g., a11 of FIG. 16) while the power of the first frequency f1 is applied to the antenna 230 and the phase of the impedance corresponding to the antenna 230 increases from the second phase (e.g., a12 of FIG. 16) to a third phase (e.g., a22 of FIG. 17) which is greater by a specified level or more than the second phase (e.g., a12 of FIG. 16) while the power of the second frequency f2 is applied to the antenna 230, the electronic device 101 may identify that the object of the first type (e.g., the conductor) is approaching the electronic device 101. For example, the electronic device 101 may identify that the object of the first type (e.g., the conductor is approaching the electronic device 101, based on the phase of the impedance corresponding to the antenna 230 being the first phase (e.g., a21 of FIG. 17) while the power of the first frequency f1 is applied to the antenna 230 and the phase of the impedance corresponding to the antenna 230 being the second phase (e.g., a22 of FIG. 17) greater than the first phase (e.g., a21 of FIG. 17) while the power of the second frequency f2 is applied to the antenna 230.

An operation of the electronic device 101 identifying the type of the external object (e.g., 181 or 192 of FIG. 1) adjacent to the electronic device 101 according to FIG. 16, FIG. 17, and FIG. 18 is for illustration. The electronic device 101 may identify the type of the external object (e.g., 181 or 192 of FIG. 1) adjacent to the electronic device 101, based on the phase of the impedance corresponding to the antenna 230 by including the antenna 230 (e.g., the first antenna 300 of FIG. 9 or the third antenna 1400 of FIG. 14).

Those skilled in the art will understand that the various example embodiments described herein may be organically applied to each other within the scope of application. For example, those skilled in the art will understand that the various embodiments may be applied while at least some of the operations of an embodiment described herein are omitted or be applied while at least some of the operations of an embodiment and at least some of the operations of another embodiment are organically connected.

According to an embodiment, an example electronic device 101 may include a resonator 210, 910, 1010a, 1010b, or 1410, a power circuit 220 configured to provide power to the resonator 210, 910, 1010a, 1010b, or 1410, an antenna 230, 300, 600, or 1400, a high-frequency source 240 configured to provide power to the antenna 230, 300, 600, or 1400, and a controller 260, comprising circuitry. The controller 260 may be configured to control the power circuit 220 to provide first power having a first frequency to the resonator 210, 910, 1010a, 1010b, or 1410 in order to wirelessly provide power to an external wireless power reception device 195. The controller 260 may be configured to control the high-frequency source 240 to provide at least one second power having a frequency different from the first frequency to the antenna 230, 300, 600, or 1400. The controller 260 may be configured to identify at least one phase of impedance corresponding to the antenna 230, 300, 600, or 1400 while the at least second power is applied to the antenna 230, 300, 600, or 1400. The controller 260 may be configured to identify a type of an external object 181 or 192 adjacent to the electronic device 101, based on the at least one phase. The antenna 230, 300, 600, or 1400 may be an antenna in which currents in the same direction are formed by the at least one second power.

According to an example embodiment, the antenna 230, 300, 600, or 1400 may include a plurality of sub-antennas 310, 610, or 1419 and a plurality of dividing parts 320, 620, or 1439.

According to an example embodiment, the plurality of dividing parts 320, 620, or 1439 may be formed between the plurality of sub-antennas 310, 610, or 1419. The plurality of dividing parts 320, 620, or 1439 may operate as a capacitor respectively.

According to an example embodiment, the plurality of dividing parts 620 or 1439 may be formed in an interdigital capacitor structure by the plurality of sub-antennas 610 or 1419.

According to an example embodiment, the antenna 230, 300, 600, or 1400 may be formed corresponding to a form of the resonator 210, 910, 1010a, 1010b, or 1410 by the plurality of sub-antennas 310, 610, or 1419.

According to an example embodiment, the antenna 230, 300, 600, or 1400 may be formed in a ring shape by the plurality of sub-antennas 310, 610, or 1419.

According to an example embodiment, the controller 260 may be configured to control the high-frequency source 240 to provide the at least one second power having the frequency different from the first frequency to the antenna 230, 300, 600, or 1400 in a period overlapping at least partly with a period in which the first power is applied to the resonator 210, 910, 1010a, 1010b, or 1410.

According to an example embodiment, the at least one second power may include power having a second frequency. The controller 260 may be configured to identify a plurality of phases of the impedance corresponding to the antenna 230, 300, 600, or 1400 at a plurality of time points while the power having the second frequency is applied to the antenna 230, 300, 600, or 1400. The controller 260 may be configured to identify the type of the external object 181 or 192 adjacent to the electronic device 101, based on the plurality of phases at the plurality of time points.

According to an example embodiment, the controller 260 may be configured to identify a first phase of the impedance corresponding to the antenna 230, 300, 600, or 1400 at a first time point and identify a second phase of the impedance corresponding to the antenna 230, 300, 600, or 1400 at a second time point after the first time point while the power having the second frequency is applied to the antenna 230, 300, 600, or 1400. The controller 260 may be configured to identify the type of the external object 181 or 192 adjacent to the electronic device 101 as a first type, based on the level of the second phase being smaller by a specified level or more than the level of the first phase.

According to an example embodiment, the controller 260 may be configured to identify the type of the external object 181 or 192 adjacent to the electronic device 101 as a second type, based on the level of the second phase being maintained in a designated range including the level of the first phase.

According to an example embodiment, the first type may be a human body. The second type may be a conductor.

According to an example embodiment, the at least one second power may include the power having the second frequency and power having a third frequency. The controller 260 may be configured to identify a plurality of first phases of the impedance corresponding to the antenna 230, 300, 600, or 1400 at a plurality of time points while the power having the second frequency is applied to the antenna 230, 300, 600, or 1400. The controller 260 may be configured to identify a plurality of second phases of the impedance corresponding to the antenna 230, 300, 600, or 1400 at a plurality of time points while the power having the third frequency is applied to the antenna 230, 300, 600, or 1400. The controller 260 may be configured to identify the type of the external object 181 or 192 adjacent to the electronic device 101, based on the plurality of first phases and the plurality of second phases.

According to an example embodiment, the controller 260 may be configured to identify a third phase of the impedance corresponding to the antenna 230, 300, 600, or 1400 at a third time point and identify a fourth phase of the impedance corresponding to the antenna 230, 300, 600, or 1400 at a fourth time point while the power having the second frequency is applied to the antenna 230, 300, 600, or 1400. The controller 260 may be configured to identify a fifth phase of the impedance corresponding to the antenna 230, 300, 600, or 1400 at a fifth time point after the third time point and identify a sixth phase of the impedance corresponding to the antenna 230, 300, 600, or 1400 at a sixth time point after the fourth time point while the power having the third frequency is applied to the antenna 230, 300, 600, or 1400. The controller 260 may be configured to identify the type of the external object 181 or 192 adjacent to the electronic device 101 as the second type, based on the level of the fifth phase being maintained in a designated range including the level of the third phase and the level of the sixth phase being greater by a specified level or more than the level of the fourth phase.

According to an example embodiment, a method of operating an electronic device 101 may include controlling a power circuit 220 of the electronic device 101 to provide first power having a first frequency to a resonator 210, 910, 1010a, 1010b, or 1410 of the electronic device 101 in order to wirelessly provide power to an external wireless power reception device 195. The method may include controlling a high-frequency source 240 of the electronic device 101 to provide at least one second power having a frequency different from the first frequency to an antenna 230, 300, 600, or 1400 of the electronic device 101. The method may include identifying at least one phase of impedance corresponding to the antenna 230, 300, 600, or 1400 while the at least second power is applied to the antenna 230, 300, 600, or 1400. The method may include identifying a type of an external object 181 or 192 adjacent to the electronic device 101, based on the at least one phase. The antenna 230, 300, 600, or 1400 may be an antenna in which currents in the same direction are formed by the at least one second power.

According to an example embodiment, the antenna 230, 300, 600, or 1400 may include a plurality of sub-antennas 310, 610, or 1419 and a plurality of dividing parts 320, 620, or 1439.

According to an example embodiment, the plurality of dividing parts 320, 620, or 1439 may be formed between the plurality of sub-antennas 310, 610, or 1419. The plurality of dividing parts 320, 620, or 1439 may operate as a capacitor respectively.

According to an example embodiment, the plurality of dividing parts 620 or 1439 may be formed in an interdigital capacitor structure by the plurality of sub-antennas 610 or 1419.

According to an example embodiment, the antenna 230, 300, 600, or 1400 may be formed corresponding to a form of the resonator 210, 910, 1010a, 1010b, or 1410 by the plurality of sub-antennas 310, 610, or 1419.

According to an example embodiment, the antenna 230, 300, 600, or 1400 may be formed in a ring shape by the plurality of sub-antennas 310, 610, or 1419.

According to an example embodiment, the method may include controlling the high-frequency source 240 to provide the at least one second power having the frequency different from the first frequency to the antenna 230, 300, 600, or 1400 in a period overlapping at least partly with a period in which the first power is applied to the resonator 210, 910, 1010a, 1010b, or 1410.

According to an example embodiment, the at least one second power may include power having a second frequency. The method may include identifying a plurality of phases of the impedance corresponding to the antenna 230, 300, 600, or 1400 at a plurality of time points while the power having the second frequency is applied to the antenna 230, 300, 600, or 1400. The method may include identifying the type of the external object 181 or 192 adjacent to the electronic device 101, based on the plurality of phases at the plurality of time points.

According to an example embodiment, the method may include identifying a first phase of the impedance corresponding to the antenna 230, 300, 600, or 1400 at a first time point and identifying a second phase of the impedance corresponding to the antenna 230, 300, 600, or 1400 at a second time point after the first time point while the power having the second frequency is applied to the antenna 230, 300, 600, or 1400. The method may include identifying the type of the external object 181 adjacent to the electronic device 101 as a first type, based on the level of the second phase being smaller by a specified level or more than the level of the first phase.

According to an example embodiment, the method may include identifying the type of the external object 192 adjacent to the electronic device 101 as a second type, based on the level of the second phase being maintained in a designated range including the level of the first phase.

According to an example embodiment, the first type may be a human body. The second type may be a conductor.

According to an example embodiment, the at least one second power may include the power having the second frequency and power having a third frequency. The method may include identifying a plurality of first phases of the impedance corresponding to the antenna 230, 300, 600, or 1400 at a plurality of time points while the power having the second frequency is applied to the antenna 230, 300, 600, or 1400. The method may include identifying a plurality of second phases of the impedance corresponding to the antenna 230, 300, 600, or 1400 at a plurality of time points while the power having the third frequency is applied to the antenna 230, 300, 600, or 1400. The method may include identifying the type of the external object 181 or 192 adjacent to the electronic device 101, based on the plurality of first phases and the plurality of second phases.

According to an example embodiment, the method may include identifying a third phase of the impedance corresponding to the antenna 230, 300, 600, or 1400 at a third time point and identifying a fourth phase of the impedance corresponding to the antenna 230, 300, 600, or 1400 at a fourth time point while the power having the second frequency is applied to the antenna 230, 300, 600, or 1400. The method may include identifying a fifth phase of the impedance corresponding to the antenna 230, 300, 600, or 1400 at a fifth time point after the third time point and identifying a sixth phase of the impedance corresponding to the antenna 230, 300, 600, or 1400 at a sixth time point after the fourth time point while the power having the third frequency is applied to the antenna 230, 300, 600, or 1400. The method may include identifying the type of the external object 192 adjacent to the electronic device 101 as the second type, based on the level of the fifth phase being maintained in a designated range including the level of the third phase and the level of the sixth phase being greater by a specified level or more than the level of the fourth phase.

According to an example embodiment, a non-transitory computer-readable recording medium may store instructions configured to perform at least one operation by a controller 260 of an electronic device 101, and the at least one operation may include an operation of controlling a power circuit 220 of the electronic device 101 to provide first power having a first frequency to a resonator 210, 910, 1010a, 1010b, or 1410 of the electronic device 101 in order to wirelessly provide power to an external wireless power reception device 195. The at least one operation may include an operation of controlling a high-frequency source 240 of the electronic device 101 to provide at least one second power having a frequency different from the first frequency to an antenna 230, 300, 600, or 1400 of the electronic device 101. The at least one operation may include an operation of identifying at least one phase of impedance corresponding to the antenna 230, 300, 600, or 1400 while the at least second power is applied to the antenna 230, 300, 600, or 1400. The at least one operation may include an operation of identifying a type of an external object 181 or 192 adjacent to the electronic device 101, based on the at least one phase. The antenna 230, 300, 600, or 1400 may be an antenna in which currents in the same direction are formed by the at least one second power.

According to an example embodiment, the antenna 230, 300, 600, or 1400 may include a plurality of sub-antennas 310, 610, or 1419 and a plurality of dividing parts 320, 620, or 1439.

According to an example embodiment, the plurality of dividing parts 320, 620, or 1439 may be formed between the plurality of sub-antennas 310, 610, or 1419. Each of the plurality of dividing parts 320, 620, or 1439 may operate as a capacitor.

According to an example embodiment, the plurality of dividing parts 620 or 1439 may be formed in an interdigital capacitor structure by the plurality of sub-antennas 610 or 1419.

According to an example embodiment, the antenna 230, 300, 600, or 1400 may be formed corresponding to a form of the resonator 210, 910, 1010a, 1010b, or 1410 by the plurality of sub-antennas 310, 610, or 1419.

According to an example embodiment, the antenna 230, 300, 600, or 1400 may be formed in a ring shape by the plurality of sub-antennas 310, 610, or 1419.

According to an example embodiment, the at least one operation may include an operation of controlling the high-frequency source 240 to provide the at least one second power having the frequency different from the first frequency to the antenna 230, 300, 600, or 1400 in a period overlapping at least partly with a period in which the first power is applied to the resonator 210, 910, 1010a, 1010b, or 1410.

According to an example embodiment, the at least one second power may include power having a second frequency. The at least one operation may include an operation of identifying a plurality of phases of the impedance corresponding to the antenna 230, 300, 600, or 1400 at a plurality of time points while the power having the second frequency is applied to the antenna 230, 300, 600, or 1400. The at least one operation may include an operation of identifying the type of the external object 181 or 192 adjacent to the electronic device 101, based on the plurality of phases at the plurality of time points.

According to an example embodiment, the at least one operation may include an operation of identifying a first phase of the impedance corresponding to the antenna 230, 300, 600, or 1400 at a first time point and identifying a second phase of the impedance corresponding to the antenna 230, 300, 600, or 1400 at a second time point after the first time point while the power having the second frequency is applied to the antenna 230, 300, 600, or 1400. The at least one operation may include an operation of identifying the type of the external object 181 adjacent to the electronic device 101 as a first type, based on the level of the second phase being smaller by a specified level or more than the level of the first phase.

According to an example embodiment, the at least one operation may include an operation of identifying the type of the external object 192 adjacent to the electronic device 101 as a second type, based on the level of the second phase being maintained in a designated range including the level of the first phase.

According to an example embodiment, the first type may be a human body. The second type may be a conductor.

According to an example embodiment, the at least one second power may include the power having the second frequency and power having a third frequency. The at least one operation may include an operation of identifying a plurality of first phases of the impedance corresponding to the antenna 230, 300, 600, or 1400 at a plurality of time points while the power having the second frequency is applied to the antenna 230, 300, 600, or 1400. The at least one operation may include an operation of identifying a plurality of second phases of the impedance corresponding to the antenna 230, 300, 600, or 1400 at a plurality of time points while the power having the third frequency is applied to the antenna 230, 300, 600, or 1400. The at least one operation may include an operation of identifying the type of the external object 181 or 192 adjacent to the electronic device 101, based on the plurality of first phases and the plurality of second phases.

According to an example embodiment, the at least one operation may include an operation of identifying a third phase of the impedance corresponding to the antenna 230, 300, 600, or 1400 at a third time point and identifying a fourth phase of the impedance corresponding to the antenna 230, 300, 600, or 1400 at a fourth time point while the power having the second frequency is applied to the antenna 230, 300, 600, or 1400. The at least one operation may include an operation of identifying a fifth phase of the impedance corresponding to the antenna 230, 300, 600, or 1400 at a fifth time point after the third time point and identifying a sixth phase of the impedance corresponding to the antenna 230, 300, 600, or 1400 at a sixth time point after the fourth time point while the power having the third frequency is applied to the antenna 230, 300, 600, or 1400. The at least one operation may include an operation of identifying the type of the external object 192 adjacent to the electronic device 101 as the second type, based on the level of the fifth phase being maintained in a designated range including the level of the third phase and the level of the sixth phase being greater by a specified level or more than the level of the fourth phase.

According to an example embodiment, an antenna 230, 300, 600, or 1400 included in an electronic device 101 may be an antenna in which currents in the same direction are formed by AC power applied to the antenna 230, 300, 600, or 1400. A controller 260 of the electronic device 101 may be configured to control a power circuit 220 of the electronic device 101 to provide first power having a first frequency to a resonator 210, 910, 1010a, 1010b, or 1410 of the electronic device 101 in order to wirelessly provide power to an external wireless power reception device 195. The controller 260 may be configured to control a high-frequency source 240 of the electronic device 101 to provide at least one second power having a frequency different from the first frequency to the antenna 230, 300, 600, or 1400. The controller 260 may be configured to identify at least one phase of impedance corresponding to the antenna 230, 300, 600, or 1400 while the at least second power is applied to the antenna 230, 300, 600, or 1400. The controller 260 may be configured to identify a type of an external object 181 or 192 adjacent to the electronic device 101, based on the at least one phase.

According to an example embodiment, the antenna 230, 300, 600, or 1400 may include a plurality of sub-antennas 310, 610, or 1419 and a plurality of dividing parts 320, 620, or 1439.

According to an example embodiment, the plurality of dividing parts 320, 620, or 1439 may be formed between the plurality of sub-antennas 310, 610, or 1419. Each of the plurality of dividing parts 320, 620, or 1439 may operate as a capacitor.

According to an example embodiment, the plurality of dividing parts 620 or 1439 may be formed in an interdigital capacitor structure by the plurality of sub-antennas 610 or 1419.

According to an example embodiment, the antenna 230, 300, 600, or 1400 may be formed corresponding to a form of the resonator 210, 910, 1010a, 1010b, or 1410 by the plurality of sub-antennas 310, 610, or 1419.

According to an example embodiment, the antenna 230, 300, 600, or 1400 may be formed in a ring shape by the plurality of sub-antennas 310, 610, or 1419.

According to an example embodiment, the controller 260 may be configured to identify the type of an external object 181 or 192 adjacent to the electronic device 101 as a conductor or a human body, based on the at least one phase.

The electronic device according to embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used in connection with various embodiments of the disclosure, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software including one or more instructions that are stored in a storage medium that is readable by a machine (e.g., the electronic device 101). For example, a processor (e.g., the controller) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Wherein, the “non-transitory” storage medium is a tangible device, and may not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by those skilled in the art that various modifications, alternatives and/or variations of the various example embodiments may be made without departing from the true technical spirit and full technical scope of the disclosure, including the appended claims and their equivalents. It will also be understood that any of the embodiment(s) described herein may be used in conjunction with any other embodiment(s) described herein.

What is claimed is:

1. An electronic device comprising:
a resonator;
a power circuit configured to provide power to the resonator;
an antenna;
a high-frequency source configured to provide power to the antenna; and
a controller, comprising circuitry,
wherein the controller is configured to cause the electronic device to:
control the power circuit to provide first power having a first frequency to the resonator to wirelessly provide power to an external wireless power reception device;
control the high-frequency source to provide at least one second power having a frequency different from the first frequency to the antenna;
identify at least one phase of impedance corresponding to the antenna while the at least second power is applied to the antenna; and
identify a type of an external object adjacent to the electronic device, based on the at least one phase, and
wherein the antenna includes an antenna configured such that currents in the same direction are formed by the at least one second power.

2. The electronic device of claim 1, wherein the antenna comprises a plurality of sub-antennas and a plurality of dividing parts.

3. The electronic device of claim 2, wherein the plurality of dividing parts is provided between the plurality of sub-antennas, and
wherein the plurality of dividing parts are configured to operate as a capacitor respectively.

4. The electronic device of claim 3, wherein the plurality of dividing parts is provided in an interdigital capacitor structure by the plurality of sub-antennas.

5. The electronic device of claim 2, wherein the antenna corresponds to a form of the resonator by the plurality of sub-antennas.

6. The electronic device of claim 5, wherein the antenna is formed in a ring shape by the plurality of sub-antennas.

7. The electronic device of claim 1, wherein the controller is configured to control the high-frequency source to provide the at least one second power having the frequency different from the first frequency to the antenna in a period overlapping at least partly with a period in which the first power is applied to the resonator.

8. The electronic device of claim 1, wherein the at least one second power comprises power having a second frequency, and
wherein the controller is configured to:
identify a plurality of phases of the impedance corresponding to the antenna at a plurality of time points while the power having the second frequency is applied to the antenna; and
identify the type of the external object adjacent to the electronic device, based on the plurality of phases at the plurality of time points.

9. The electronic device of claim 8, wherein the controller is configured to:
identify a first phase of the impedance corresponding to the antenna at a first time point and identify a second phase of the impedance corresponding to the antenna at a second time point after the first time point while the power having the second frequency is applied to the antenna; and
identify the type of the external object adjacent to the electronic device as a first type, based on a level of the second phase being smaller by a specified level or more than a level of the first phase.

10. The electronic device of claim 9, wherein the controller is configured to identify a type of external object adjacent to the electronic device as a second type, based on the level of the second phase being maintained in a designated range comprising the level of the first phase.

11. The electronic device of claim 10, wherein the first type is a human body, and
wherein the second type is a conductor.

12. The electronic device of claim 1, wherein the at least one second power comprises power having the second frequency and power having a third frequency, and
wherein the controller is configured to:
identify a plurality of first phases of the impedance corresponding to the antenna at a plurality of time points while the power having the second frequency is applied to the antenna;
identify a plurality of second phases of the impedance corresponding to the antenna at a plurality of time points while the power having the third frequency is applied to the antenna; and
identify the type of the external object adjacent to the electronic device, based on the plurality of first phases and the plurality of second phases.

13. The electronic device of claim 12, wherein the controller is configured to:
identify a third phase of the impedance corresponding to the antenna at a third time point and identify a fourth phase of the impedance corresponding to the antenna at a fourth time point while the power having the second frequency is applied to the antenna;
identify a fifth phase of the impedance corresponding to the antenna at a fifth time point after the third time point and identify a sixth phase of the impedance corresponding to the antenna at a sixth time point after the fourth time point while the power having the third frequency is applied to the antenna; and
identify the type of the external object adjacent to the electronic device as the second type, based on a level of the fifth phase being maintained in a designated range comprising a level of the third phase and a level of the sixth phase being greater by a specified level or more than a level of the fourth phase.

14. An antenna included in an electronic device,
the antenna comprising an antenna configured so that currents in the same direction are formed by AC power applied to the antenna,
wherein a controller, comprising circuitry, of the electronic device is configured to:
control a power circuit of the electronic device to provide first power having a first frequency to a resonator of the electronic device to wirelessly provide power to an external wireless power reception device;
control a high-frequency source of the electronic device to provide at least one second power having a frequency different from the first frequency to the antenna;
identify at least one phase of impedance corresponding to the antenna while the at least second power is applied to the antenna; and
identify a type of an external object adjacent to the electronic device, based on the at least one phase.

15. The antenna of claim 14, wherein the antenna comprises a plurality of sub-antennas and a plurality of dividing parts.

16. The antenna of claim 15, wherein the plurality of dividing parts is provided between the plurality of sub-antennas, and
wherein the plurality of dividing parts are configured to operate as a capacitor respectively.

17. The antenna of claim 16, wherein the plurality of dividing parts is provided in an interdigital capacitor structure by the plurality of sub-antennas.

18. The antenna of claim 15, wherein the antenna corresponds to a form of the resonator by the plurality of sub-antennas.

19. The antenna of claim 18, wherein the antenna is formed in a ring shape by the plurality of sub-antennas.

20. The antenna of claim 14, wherein the controller is configured to identify the type of the external object adjacent to the electronic device as a conductor or a human body, based on the at least one phase.
